(19) United States
(12) Patent Application Publication
(10) Pub. No.: US 2016/0329387 A1
(43) Pub. Date: Nov. 10, 2016

(54) ORGANIC LIGHT EMITTING DIODE

(71) Applicant: KONINKLIJKE PHILIPS N.V., Eindhoven (NL)

(72) Inventors: Senthilnathan MOHANAN, Aachen (DE); Christoph RICKERS, Wendhausen (DE); Marc WENDELS, Aachen (DE); Soeren HARTMANN, Baesweiler (DE)

(21) Appl. No.: 15/109,895

(22) PCT Filed: Dec. 31, 2014
(86) PCT No.: PCT/EP2014/079489

§ 371 Date: Jul. 6, 2016

(30) Foreign Application Priority Data
Jan. 14, 2014 (EP) 14151156.8

(51) Int. Cl. H01L 27/32; H01L 51/50; H01L 51/56; H01L 51/52

(52) U.S. Cl. CPC H01L 27/3246; H01L 51/5206; H01L 51/5221; H01L 51/5012; H01L 51/56; H01L 2251/308; H01L 2251/301; H01L 2227/323

(57) ABSTRACT

The present invention relates to organic light emitting diodes (OLEDs) wherein organic photoresist layers are used as dielectric layers for electrical isolation. When organic photoresist layers are used as dielectric layers in OLEDs, a problem called “pixel shrinkage” may occur. According to the invention, the problem of pixel shrinkage can be solved by using an acrylic resin such as methyl methacrylate or a solution of polyimide in gamma-butyrolactone to form the dielectric layer. There is provided an organic light emitting diode (100) comprising: a substrate layer (110); a first electrode layer (120); a second electrode layer (130); an active layer (140) in-between the first and second electrode layers (120, 130); and a dielectric layer (150) configured to provide an electrical isolation between the first and second electrodes (120, 130). The dielectric layer (150) comprises a dielectric material configured to produce a reduced amount of or no by-products during a curing process.

### FIELD OF THE INVENTION

The invention relates to an organic light emitting diode, a fabrication apparatus for fabricating an organic light emitting diode, and a fabrication method for fabricating an organic light emitting diode.

### BACKGROUND OF THE INVENTION

US-2013/009162-A1 discloses an organic light-emitting display device including a substrate; a plurality of thin film transistors (TFTs) on the substrate; a plurality of first electrodes respectively on the TFTs; a pixel-defining layer between the first electrodes, the pixel-defining layer including a covered portion and an uncovered portion; a plurality of organic layers respectively on the first electrodes, each organic layer including an emission layer; a second electrode covering at least a part of the organic layers and the pixel-defining layer, a portion of the pixel-defining layer covered by the second electrode defining the covered portion, wherein at least one outgassing hole is in the uncovered portion of the pixel-defining layer, the uncovered portion being an exposed area of the pixel-defining layer.

One of the problems which conventional OLED lighting devices (as well as displays) face is pixel shrinkage, which involves the reduction of the lighting area over time due to deterioration of the functional layers.

### SUMMARY OF THE INVENTION

It is an object of the present invention to reduce or eliminate pixel shrinkage, i.e., the reduction of the lighting area over time.

In a first aspect of the invention, there is provided an organic light emitting diode (OLED). The organic light emitting diode comprises a substrate layer; a first electrode layer, wherein the first electrode layer is arranged on the substrate layer; a second electrode layer; an active layer for emitting visible light, wherein the active layer is arranged in-between the first and second electrode layers; and a dielectric layer configured to provide an electrical isolation between the first and second electrodes.

The dielectric layer is deposited as a pattern on the first electrode layer, covering at least one edge of at least one of the first and second electrodes. Also, at least one side of the dielectric layer is covered by the second electrode layer, preferably, where the first electrode layer is patterned.

The dielectric layer comprises a dielectric material chosen from the group consisting of an acrylic resin, an acrylic-based resin, a methyl methacrylate, an unsaturated polyester, a polyurethane acrylate, an epoxy acrylate, a polyimide, and an epoxy imide. Such a dielectric layer will be configured to produce a reduced amount of or no by-products during a curing process. The proposed classes of dielectric materials will suppress the pixel shrinkage effect and provide a cost-effective application process.

The first aspect of the present invention relates to recognizing that the curing step is crucial as it actively may create byproducts depending on the material and that those trigger pixel shrinkage. In particular, the present invention involves recognizing that the curing process itself might produce the by-products. Preferred embodiments of the invention identify suitable materials avoiding or suppressing pixel shrinkage by producing no or significantly less volatiles during the curing process.

Dielectric materials chosen from the group consisting of an acrylic resin, an acrylic-based resin, a methyl methacrylate, an unsaturated polyester, a polyurethane acrylate, and an epoxy acrylate are dielectric materials which are polymerized/cured by addition polymerization that does not produce any by-products. Acrylic based resins (such as, e.g., methyl methacrylate) undergo chain growth polymerization that does not produce by-products and also possesses excellent dielectric and hydrophobic characteristics. Acrylic resin can be cured by thermal processes and by ultraviolet radiation (UV curing) by adding suitable photo-initiators. Investigation of acrylic resin as a dielectric material has shown that the pixel shrinkage can be suppressed significantly compared to the standard photo resist based dielectric materials. The substrates which are handled in ambient air after deposition and curing of acrylic resin based dielectric layer do not show any pixel shrinkage. In principle, pixel shrinkage that causes reduction of lighting area in OLED devices is due to the volatiles released from the dielectric material over time. A solution to suppress or reduce pixel shrinkage would be to select the material that releases significantly lower or no volatiles under operating conditions. Acrylic polymers are polymerized by addition polymerization, and therefore do not produce any byproducts upon the curing process (i.e., upon the transformation from liquid to solid form). In particular, the byproduct could be a potential volatile material that could be trapped in that material and released over time. Further, very low moisture absorption (hydrophobic behavior) results in significantly lower water content in the cured material. Therefore pixel shrinkage due to the moisture released during OLED operation is reduced.

When the dielectric material comprises a polyimide, the polymide may be dispersed in gamma butyrolactone. In other words, in a preferred embodiment, the dielectric material comprises a polymerised material dispersed in a solvent (such as, e.g., polyimide in gamma butyrolactone). Since the functional dielectric material has already been polymerized, it does not produce any volatile by-product during post thermal baking (to evaporate the solvent). In the case of polyimides, due to high thermal and chemical inertness, the chemical decomposition rate is reduced, as the latter could release volatiles during operating conditions. In addition, polymides exhibit very low moisture absorption and can also be processed as a prepolymerized substance in a solvent (such as, e.g., gamma butyrolactone), where the film is formed by just evaporating the solvent. Thereby no or significantly less byproducts are formed upon curing, as here it is basically a drying rather than a curing process. In a further preferred embodiment of the invention, the dielectric material comprises: C═O; and/or C—O; and/or OC═O; and/or CH3CO—OCH3. By choosing a dielectric material with one or more of these functional groups, an improved UV stability may be achieved. UV irradiation (such as, e.g., sunlight) causes the disintegration of the dielectric material resulting in volatile byproducts and causing additional pixel shrinkage. UV stability can be improved by choosing materials with higher bond dissociation energy or materials with UV stabilizers, which can also be photoinitiators (i.e., initiating polymerization) that absorb UV irradiation and thereby avoid chain scission of polymers. To improve UV stability of the dielectric material from UV irradiance (which refers to wavelengths of 300 nm to 400 nm), materials with bond dissociation energy greater than 400 kJ/mol are preferable. This would be the requirement for material selection and acrylates would be one of the materials that would satisfy this requirement. Namely, for C═O, the bond dissociation energy amounts to 749 kJ/mol (7.8 eV). For C—O, the bond dissociation energy amounts to 1076 kJ/mol (11.1 eV). For OC═O, the bond dissociation energy amounts to 532 kJ/mol (5.5 eV). For CH3CO—OCH3, the bond dissociation energy amounts to 406 kJ/mol (4.2 eV).

In a further preferred embodiment of the invention, the dielectric material is solvent-free. Preferably, the dielectric material is hydrophobic. By choosing the material to be solvent-free and to display hydrophobic behaviour, moisture intake can be avoided.

In a further preferred embodiment of the invention, the dielectric material is at least partially transparent to visible light. Acrylic and polyimide based dielectric layers exhibit excellent transparency due to low absorption of light in the visible range and they can also be processed by cost-effective direct printing techniques with high material yield. Both the materials can be cured in a single processing step which would increase the product yield. Thermal baking post treatment is not required for solvent free acrylic resin due to the absence of solvent or any by-products upon polymerization or curing by UV irradiation or by a thermal process.

The dielectric layer provides an electrical isolation between the electrodes and covers the edges of the electrodes which otherwise may lead to the failure of the OLED device. Failure of the OLED device is caused by the high electric field at the edges, but it is also a manufacturing issue, as shadow masks for the electrode deposition may locally scratch the organic layers, which would then indeed realize a direct contact between the electrodes. The dielectric layer also allows certain degree of tolerance towards the misalignment of the mask during organic and cathode layer deposition.

In a further preferred embodiment of the invention, the dielectric layer is deposited by a direct printing technique. By depositing the dielectric layer via a direct printing technique, acrylic and polyimide based dielectric layers can be processed in a cost-effective manner with high material yield.

In a further preferred embodiment of the invention, the first electrode layer is an anode layer, and the second electrode layer is a cathode layer. Preferably, the anode layer comprises an Indium-Tin-Oxide layer. Preferably, the cathode layer comprises an Aluminium layer.

In a further preferred embodiment of the invention, the first electrode layer is a patterned transparent electrode layer.

In a further preferred embodiment of the invention, the second electrode layer comprises a transparent electrode layer and/or a light-reflecting layer configured to pass visible light emitted from the active layer through the substrate layer. The second electrode layer may also be, e.g., semi-transparent, e.g. thin, Al/Ag.

In a further preferred embodiment of the invention, the first and second electrode layers both comprises a transparent electrode layer. The electrode layers may be, e.g., semi-transparent, e.g. thin, Al/Ag.

In a further preferred embodiment of the invention, the dielectric material comprises a material with higher bond dissociation energy. Preferably, the dielectric material comprises a material with UV sensitive photo initiators. Preferably, the dielectric material comprises UV curable acrylic inks. By choosing the dielectric material in the above-described manner, an improved UV stability may be achieved.

In a second aspect of the invention, there is provided a fabrication apparatus for fabricating an organic light emitting diode. The fabrication apparatus comprises: a substrate providing unit for providing a substrate layer; an electrode arranging unit for arranging a first electrode layer on the substrate layer; an electrode providing unit for providing a second electrode layer; an active layer arranging unit for arranging an active layer in-between the first and second electrode layers; and a dielectric layer providing unit for providing a dielectric layer to provide an electrical isolation between the first and second electrodes. The dielectric layer comprises a dielectric material configured to produce a reduced amount of or no by-products during a curing process.

In a third aspect of the invention, there is provided a fabrication method for fabricating an organic light emitting diode, wherein the fabrication method comprises the steps of providing a substrate layer; arranging a first electrode layer on the substrate layer; providing an active layer; providing a dielectric layer; and providing a second electrode layer. The active layer is arranged in-between the first and second electrode layers. The dielectric layer provides an electrical isolation between the first and second electrodes. The dielectric layer comprises a dielectric material configured to produce a reduced amount of or no by-products during a curing process.

It shall be understood that the organic light emitting diode of claim 1, the fabrication apparatus of claim 14 and the fabrication method of claim 15 have similar and/or identical preferred embodiments as defined in the dependent claims.

It shall be understood that a preferred embodiment of the invention can also be any combination of the dependent claims or above embodiments with the respective independent claim.

These and other aspects of the invention will be apparent from and elucidated with reference to the embodiments described hereinafter.

### BRIEF DESCRIPTION OF THE DRAWINGS

In the following drawings:

FIG. 1A shows schematically and exemplarily an embodiment of an organic light-emitting diode (OLED),

FIGS. 1B and 1C show schematically and exemplarily two further embodiments of an organic light-emitting diode (OLED),

FIGS. 1D and 1E show schematically and exemplarily two embodiments of an organic light-emitting diode (OLED) having four electrode contacts,

FIG. 2 shows schematically and exemplarily experimental data on pixel shrinkage as a function of time for different materials,

FIG. 3 shows schematically and exemplarily experimental data on pixel shrinkage as a function of time for further different materials,

FIG. 4 shows schematically and exemplarily an embodiment of a fabrication apparatus for fabricating an organic light emitting diode,

FIG. 5 shows schematically and exemplarily an embodiment of a fabrication method for fabricating an organic light emitting diode,

FIGS. 6A and 6B compare schematically and exemplarily structural differences of the device upon depositing a dielectric layer by photolithography or by inkjet printing, and

FIG. 7 shows schematically and exemplarily experimental data on pixel shrinkage as a function of time upon UV exposure.

### DETAILED DESCRIPTION OF THE EMBODIMENTS

OLED substrates comprise a dielectric layer to provide an electrical isolation between the electrodes and to cover the edges of the electrodes which otherwise may lead to failure of the OLED device due to the high electric field at the edges of the electrodes and/or damaged organic layers resulting from edges of the shadow masks for the electrode layer. The dielectric layer also allows a certain degree of tolerance towards the misalignment of the mask during organic and cathode layer deposition.

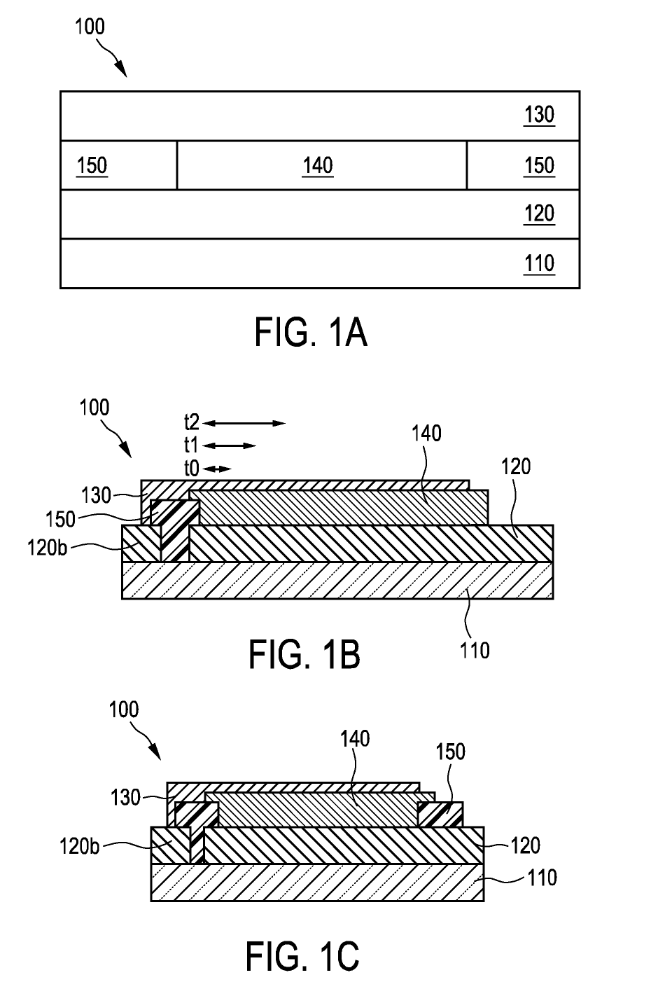

FIG. 1A shows schematically and exemplarily an embodiment of an organic light-emitting diode (OLED) 100. OLED 100 comprises a substrate 110, a first electrode 120, a second electrode 130, and an active layer 140 located in-between the first and second electrodes. Preferably, a dielectric layer 150 is locally placed to cover the edges of the organic/electrode layers 120, 130. In some embodiments (such as, e.g., the one illustrated in FIG. 1B), dielectric layer 150 may also cover the edges in the first electrode (e.g., anode) layer resulting from patterning. Namely, in the embodiment of FIG. 1B, active layer 140 stops at dielectric layer 150. However, in practice this is not necessarily the case as active layer 140 may completely overlap dielectric layer 150. In fact, active layer 140 might even get in touch with electrode section 120b as long as second electrode layer 130 extends even further than active layer 140 and directly touches electrode section 120b to make contact. The relative lateral placement of the individual layers follows from FIG. 1B. Namely, dielectric layer 150 covers the patterned area of first electrode 120 and is placed underneath the edges of second electrode 130 and active layer 140 while second electrode 130 has larger lateral extensions on the right side than active layer 140 while it is the other way around on the other side. Preferably, there is on both sides an overlap between second electrode 130 and active layer 140 to prevent direct contact between second electrode 130 and first electrode 120. An overlap of active layer 140 and dielectric layer 150 as shown is not necessarily required.

Please note that this is the most simple device design as it only comprises one contact area to the cathode layer (FIG. 1B). Other devices may comprise more complex patterns where first and second electrodes are locally contacted from different sides (see FIGS. 1D and 1E, where 131 denotes the second electrode (e.g., cathode) contact area (which may correspond, e.g., to electrode section 120b in FIG. 1B). FIG. 1E shows the same device 100 with interconnected second electrode (e.g., cathode) contact positions on the first electrode (e.g., anode) layer. This is mostly done to improve homogeneity of the device by better current injection/distribution which, however, requires additional metallization (not shown in FIG. 1E).

Photolithography is a commonly used technique to pattern the functional layers of the OLED substrates. This technique involves coating of an entire substrate with an organic photo resist material which is soft-baked to remove the solvent without degrading the photosensitivity of the resist and exposing to resist to UV light under the photo mask. The exposed (for positive resist) or the unexposed (for negative resist) region will then be dissolved in a developer solution and the patterned resist layer is hard-baked to improve the adhesion of the photo resist on to the functional layer of the substrate. Patterning of photo resist is followed by wet or dry etching of the underlying functional layer and finished by stripping off the patterned photo resist.

Conventionally, the dielectric layer in an OLED substrate is made of an organic photo resist owing to its dielectric property using photolithography process, as described above. The dielectric layer may also be made of an inorganic material (such as, e.g., metal oxides or nitrides) deposited, e.g., by vacuum deposition techniques, with subsequent patterning techniques or shadow mask deposition. Both of these steps are expensive (because they involve a multi-step patterning process) and prone to yield losses (due to particle generation).

Problems and disadvantages of the photolithography process are associated with the solvent in the photo resist and the volatile by-product produced during thermal baking of the photo resist. One of the problems which the current OLED lighting devices (as well as displays) face is called pixel shrinkage, which involves the reduction of the lighting area due to deterioration of the functional layers by the volatiles released from the dielectric layer over time.

The problem of pixel shrinkage would be of higher importance in the case of large area devices compared to the small devices where the dielectric layer is placed only along the edges of the lighting area. The distribution of electric current is critical for the large area devices and therefore, metallic grids or stripes (located within the lighting area) are used in order to improve the current distribution. In this case, the dielectric layer has to be deposited to cover the metallic grid or stripes in the active lighting area where both the edges of the dielectric layer play a role in defining the active lighting subunits. As the area covered by dielectric layer in the lighting area increases, the problem due to pixel shrinkage increases drastically resulting in the reduction of the device lifetime. In addition to this the distance between metal strips and mesh widths of a grid are in the order of magnitude of shrink rates of only a few thousand hours.

As the dielectric layer prevents the area from lighting up during the ON state, the dielectric layer may also be used to provide a pattern in the active lighting area. As the dielectric layer is deposited on the conducting electrode, it is possible to light a small area enclosed by the dielectric layer. In this way, an OLED device with signs, designs and symbols can be realized with ease. However, pixel shrinkage is detrimental for such applications, particularly for patterns with fine structures and small enclosed areas. For patterning applications, the dielectric layer is preferred to be highly transparent so that it is invisible in the OFF state. Yet, most of the photo resists are commercially produced with pigments resulting in limited availability of resist materials to choose from.

Novolac (i.e., a phenol-formaldehyde resin with a formaldehyde to phenol molar ratio of less than one) is one of the commonly used positive photo resists, which are based on phenol-formaldehyde resin. The latter undergoes a poly condensation reaction during a thermal baking process to form long chain polymers. This process results in the formation of volatile by-products with an increasing degree of polymerization. Therefore, an additional post baking step is necessary to drive out the volatile by-products. In addition, due to the presence of hydrophilic groups in phenol-formaldehyde resins, ambient moisture is absorbed during handling and storage. The absorption of moisture is unavoidable during a wet chemical cleaning process after thermal treatment of the substrate.

Usage of photo resist as a dielectric layer involves thermal processes for soft and hard baking steps to drive out the solvents and volatile by-products formed during the polymerization reaction. Scaling up of the thermal treatment process to an industrial high throughput environment will be very expensive due to the large foot print of the thermal oven and maintenance cost associated with filtering out organic vapor contents and particles to meet clean room specifications. In addition, there is a considerable and non-negligible amount of power consumption involved. Photolithography processes involve multiple processing steps (such as, e.g., depositing the photo resist, soft-baking, exposing, developing and hard-baking) to prepare a dielectric layer which would affect the process yield. In addition, a large amount of resist material is wasted while developing the resist in a wet chemical process which increases the cost.

A solution to overcome the pixel shrinkage problem is to utilize, a dielectric material 150 that does not produce any by-products (condensate) during curing or baking process and/or a dielectric material 150 that produces significantly reduced by-products during curing or baking process; wherein dielectric material 150 is preferably solvent-free and displaying hydrophobic behavior to avoid moisture intake.

In addition, dielectric material 150 is preferably transparent for patterned and transparent OLED devices 100 and is preferably suitable for cost-effective fabrication process (equipment with smaller foot print, reduced number of processing steps). Traditional resist materials used in photo-lithography are colored. As those have traditionally been used to realize dielectric layer 150, this layer is colored as well. However, there might be materials that do shrink without being colored and which may also be patterned by photo-lithography. Transparency is not necessarily related to pixel shrinkage reduction. Due to pigmentation, a colored photoresist is preferred for better optical inspection during the patterning process.

Formation of by-products during curing/baking process can be avoided by using the following types of materials 150:
Material class 1: Dielectric materials 150 which are polymerized and/or cured by addition polymerization that does not produce any by-products (such as, e.g., acrylic resin, unsaturated polyester, polyurethane acrylates, epoxy acrylates); and/or
Material class 2: Dielectric materials 150 comprising a polymerized material dispersed in a solvent (e.g., polyimide in gamma butyrolactone). Since the functional dielectric material 150 has already been polymerized, it produces no or significantly less volatile by-products during post thermal baking (to evaporate the solvent).

Acrylic based resins (such as, e.g., methyl methacrylate) that belong to “Material class 1” undergo chain growth polymerization that does not produce by-products and also possesses excellent dielectric and hydrophobic characteristics. Acrylic resin can be cured by thermal processes and by ultraviolet radiation (UV curing) by adding suitable photo-initiators. Investigation of acrylic resin as a dielectric material has shown that the pixel shrinkage can be suppressed significantly compared to the standard photo resist based dielectric materials. That is, pixel shrinkage can be promoted by heating and driving a device as it is a diffusion process. Measuring the extent of pixel shrinkage is straight forward: A device is driven, preferably in a heated environment and from time to time (such as, e.g., every several tenth to hundredth hours), the device is removed from the climate chamber and the distance from the edge of dielectric layer 150 (see FIG. 1B, t₀, t₁ and t₂ denote measuring times with t₀>0, t₁>t₀ and t₂>t₁; for a typical analysis, more than three to four measurements are acquired covering a reasonable time span) and the location where the device starts to light up is measured with an optical microscope. This way, one may determine a creep distance over time and, hence, a shrink-rate. The shrink rate is dependent of the ambient temperature, driving current, device dimensions, resist layer thickness and lateral dimensions (material volume), organic layer stack, etc. Accordingly, qualitative comparisons between different resists are possible, if the same testing conditions are chosen. By also measuring the shrink rate at ambient conditions (or use case conditions), an acceleration factor for the test inside the climate chamber can be identified for the test device and conditions.

The substrates which are handled in ambient air after deposition and curing of acrylic resin based dielectric layer 150 show reduced pixel shrinkage in comparison with the usage of a standard photo resist. An absolute acceptable value would depend on the configuration of the final product.

In principle, pixel shrinkage that causes reduction of lighting area in OLED devices 100 is due to the volatiles released from the dielectric material 150 over time. A solution to suppress or reduce pixel shrinkage would be to select the material that releases significantly lower or no volatiles under operating conditions.

Acrylic polymers are polymerized by addition polymerization, and therefore do not produce any byproducts upon the curing process (i.e., upon the transformation from liquid to solid form). In particular, the byproduct could be a potential volatile material that could be trapped in that material and released over time. Further, very low moisture absorption (hydrophobic behavior) results in significantly lower water content in the cured material. Therefore pixel shrinkage due to the moisture that is released during OLED operation is reduced.

In the case of polyimides, due to high thermal and chemical inertness, the chemical decomposition rate is reduced, as the latter could release volatiles during operating conditions. In addition, polymides exhibit very low moisture absorption and can be processed as a prepolymerized substance in a solvent (such as, e.g., gamma butyrolactone), where the film is formed by just evaporating the solvent. Thereby, no or significantly reduced byproducts are formed upon curing.

Polyacrylates and polyimides address the reduction of pixel shrinkage in OLED devices 100 due to the above mentioned properties. Examples like polyurethane, epoxy acrylates, unsaturated polyester, epoxy imide blend also possess one or more of the above mentioned properties similar to that of polyacrylates and polyimides and thereby could be a potential dielectric material with reduced pixel shrinkage in OLED devices 100.

However, polyimide and acrylates can be processed by a range of industrial printing technology (inkjet printing, screen printing, pad printing, gravure printing, etc) compared to the other materials and therefore increases their significance.

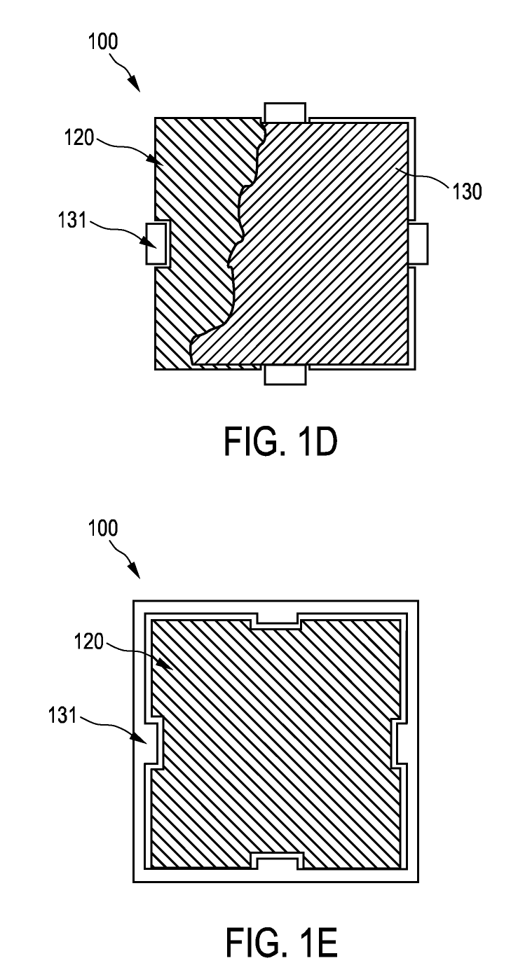

FIG. 2 shows pixel shrinkage 210 (in μm) in acrylic resin based dielectric layer 150 as a function of time 220 (in hours) during an accelerated test for the samples subjected to different post cleaning treatment (no cleaning 231, cleaning A 232, and cleaning B 233). The cleaning procedure is described in more detail herein below. No cleaning refers to simply not using any cleaning, Cleaning treatments A and B refer to applying the cleaning as described once without and once with the final UV ozone cleaning step to remove organic contaminations, or not. The reason why pixel shrinkage is smaller without cleaning is that the different materials have a different tendency to absorb moisture during the cleaning processes as all cleaning processes are wet cleaning processes. Some of them also use UV irradiation to support wetting of the substrates during cleaning or to remove organic contaminants. Usually, high UV exposure has a negative effect as it not only attacks the contaminants, but also the resist layer which consequently may have higher water uptake than in undamaged condition. Pixel shrinkage in conventionally used photo resist materials that are subjected to similar post cleaning treatments are shown as a references 341 (cleaning A) and 342 (cleaning B). As can be seen from FIG. 2, pixel shrinkage 210 in acrylic resin based dielectric layers 150 is limited to 25 μm even after 1000 hours, whereas, in conventional photo resist materials (references 241 and 242), pixel shrinkage 210 has reached a value of above 200 μm already after 300 hours. Pixel shrinkage is measured as described above. The denoted distances are those measured in the described procedure. Hence, they refer to a distance that is removed from the initial active area. This distance is not only removed on one side of the device but wherever resist material gets in contact with the organic/electrode layers. However, shrink rates on different sides may be different due to local differences in electric field strengths, current densities and temperature. Hence, calculating the size of an “effective pixel” is not straight forward from just measuring the shrink rate on one side. As explained above, it is a qualitative comparison and it is important to use the same operation conditions and device design to allow comparisons. Assuming that pixel shrinkage is uniform (i.e., that pixel shrinkage along one pixel edge is the same as pixel shrinkage along another edge) may be appropriate depending on the volume of the dielectric layer and the device architecture. One example would be a symmetric device design if also the temperature is homogeneously distributed over the device, which in turn might depend on the use conditions. For instance, homogeneity of larger devices is often affected by convection cooling, which may be different for different locations of the device and as pixel shrinkage is a diffusion process and temperature drives diffusion, in this case homogeneous shrink rates cannot be expected.

Polyimide is known for its excellent insulation property, chemical resistance and high thermal stability. Investigation of polyimide in gamma Butyrolactone (GBL) solvent (JSR Optmer AL1051) that belongs to the dielectric “Material class 2” has shown no pixel shrinkage compared to standard photo resist. OLED devices prepared from the substrates subjected to different cleaning treatment did not show any pixel shrinkage. Polyimide is by its properties as such (good insulation, chemical resistance, thermal stability) a good candidate for an insulation layer. However, polyimide is not straightforward to process and cannot be processed by a direct printing process, as it requires specific ink formulations. Further, the polymerization of polyimide also produces by-products. Therefore, using polyimide requires several thermal treatments for polymerization followed by baking cycles. This significantly increases the production cost. By using pre-polymerized material, the formation of volatile by-product can be suppressed or reduced. In photo-lithography, polyimide can, in principle, be used but it is very expensive due to several required baking steps as well as the low material yield.

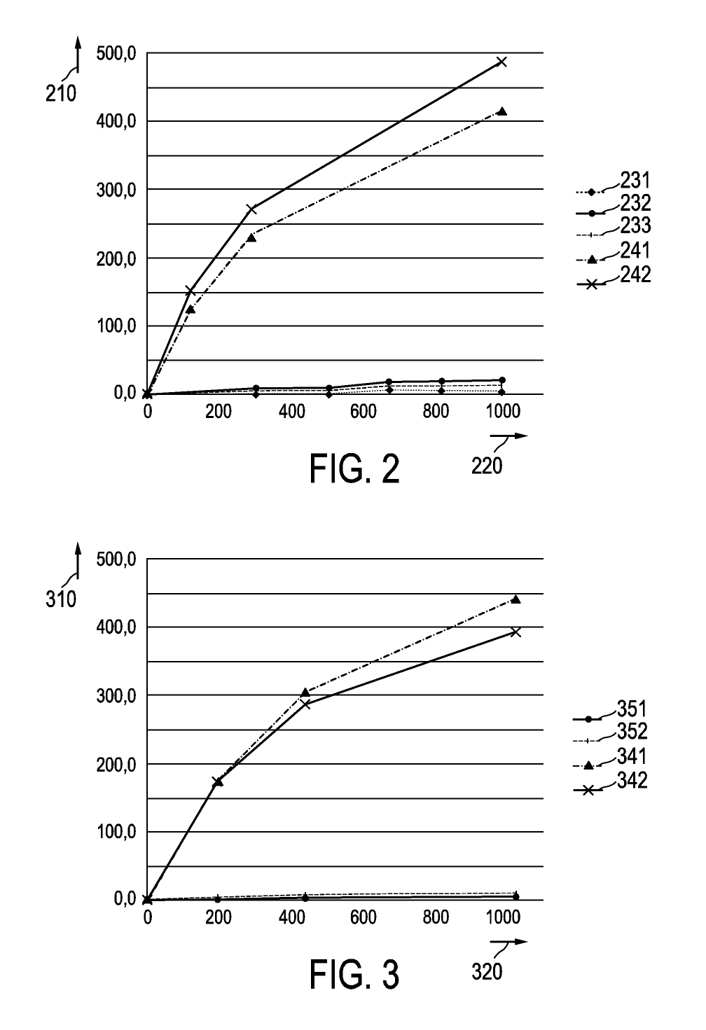

FIG. 3 shows pixel shrinkage 310 (in μm) in a polyimide dielectric layer (OptmerAL1051) as a function of time 320 (in hours) during an accelerated test for the substrates subjected to different post cleaning treatments (cleaning A 351 (i.e., using DI-water) and cleaning B 352 (i.e., using DI-water and UV-irradiation)). Pixel shrinkage 310 in the currently used photo resist material that are subjected to similar post cleaning treatments are shown as references 341 (cleaning A) and 342 (cleaning B). Pixel shrinkage results for conventional photo resist material in FIG. 3 differ from the corresponding results for conventional photo resist material in FIG. 2, because, as described above in the explanation of the measurement procedure, the results have to be acquired using the same devices, stacks, use conditions and so on. FIGS. 2 and 3 show two batches of tests, while the data shown within one diagram result from one test batch. For instance, the data is generated from samples treated exactly the same at the same time (as they went into the oven next to each other). Additional small variations may result from thickness variations of the resist material depending on the position on the original substrate. In locations with thicker resist there is more volume to comprise volatile components. Devices are prepared on substrates comprising many, sometimes more than fifty devices per substrate. On each substrate slight variations of resist thickness can be measured due to manufacturing/slit coating tolerances (from the photolithography process). The devices used for the tests are sampled from many bigger substrates, hence small variations might result from the different original locations of the devices on the substrate. The main message of the graphs should hence be the difference between traditional and new proposed resist materials which is orders of magnitudes bigger than even the spread one gets if the proposed resists are aggressively treated during cleaning with best chances for moisture uptake.

Acrylic and polyimide based dielectric layers exhibit excellent transparency due to low absorption of light in the visible range and they can also be processed by cost-effective direct printing techniques with high material yield. Both materials can be cured in a single processing step which increases the product yield. Thermal baking post treatment is not required for acrylic resin due to the absence of solvent or any by-products upon polymerization or curing by UV irradiation.

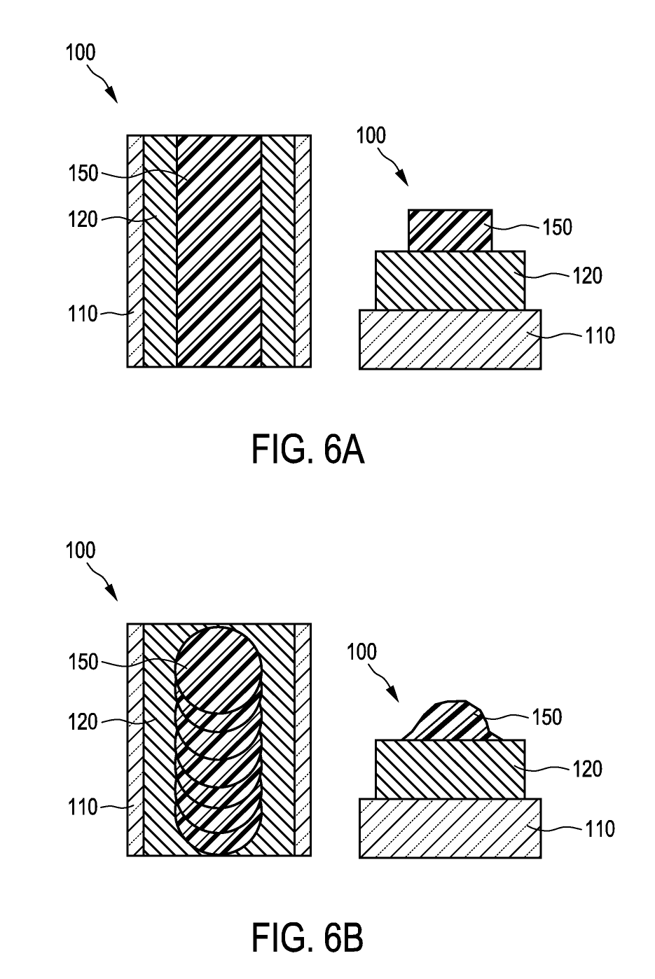

The acrylic resin based dielectric layer 150 showing no pixel shrinkage can be built using a substrate 110 with a patterned transparent anode 120. The substrate 110 can be cleaned with UV ozone to remove organic contaminants and to improve wetting of DI water which is used to remove particle contaminants with the assistance of brush rollers. The substrate 110 then can be rinsed with DI water and dried using an air knife edge. Acrylic resin 150 can be deposited along the edges of the electrodes 120, 130 or as a pattern on the anode 120, e.g., by applying an inkjet printing technique. The structural difference resulting from depositing the acrylic resin by applying an inkjet printing technique as compared to depositing acrylic resin by applying e.g. photolithography is illustrated by FIG. 6A (showing top (left panel) and cross-section (right panel) of depositing by photolithography) and 6B (showing top (left panel) and cross-section (right panel) of depositing by inkjet-printing). Depending on the wetting behavior of dielectric layer 150 on substrate 110, the inkjet printed dielectric layer (e.g., resist) might comprise less regular shapes than e.g. photo-lithography can yield, because individual drops are placed next to each other with some overlap rather than a layer covering the full area with subsequent local removal by selective etching. The individual drops then flow together (depending on material and substrate wetting properties which may comprise local variations). Also, looking at the cross section of a resist rim (see right panels of FIGS. 6A and 6B), the printed ones are more smooth while photo-lithography usually results in rectangular patterns with sharp edges (which is not necessarily an advantage in OLEDs). Note that the sketch shown in FIGS. 6A and 6B is very much simplified. Aside of that, patterning tolerances of photo lithography are much more accurate (typically on the order of 7-15 μm) as those of inkjet printing (typically on the order of 30-100 μm) which would reduce the minimum feature sizes one can achieve by printing compared to photolithography, but this is not critical for OLED devices. The deposited resin 150 is then irradiated preferably with a UV dosage of about 1000 mJ/cm² at 365 nm to complete the curing process. Further processing of the substrate 110 with dielectric layer 150 is the same as for conventional substrates to build functional OLEDs 100.

Deposition of acrylic resin 150 can be realized by a broad range of direct printing techniques (such as, e.g., inkjet, screen printing, pad printing, flexographic printing) and the required thickness can be realized by optimizing the printing process parameters. Chemical curing can be activated by UV irradiation which offers an excellent flexibility in scaling up curing process to an industrial high throughput environment due to their very high curing rate (small foot-print and low operational costs). Upon curing, solvent-free acrylic resin does not produce any organic vapor content. This simplifies the implementation of curing processes in a clean room environment with limited efforts.

Polyimide based dielectric layers 150 can be built on a cleaned substrate 110 (as mentioned herein above) by depositing polyimide:GBL ink along the edges of the electrodes 120, 130, e.g., by an inkjet printing process. Preferably, substrate 110 can be baked in a convection oven (not shown) at 190° C. for 5-15 min to evaporate the solvent and is further processed to build functional OLED devices 100. Polyimide:GBL ink does not require any post baking process in addition to thermal treatment in convection oven, as it is free of any volatile by-products and moisture.

Further to the above, an improved UV stability may be achieved as follows: UV irradiation (such as, e.g., sunlight) causes the disintegration of dielectric material 150 resulting in volatile byproducts and causing additional pixel shrinkage. UV stability can be improved by choosing materials with higher bond dissociation energy or materials with UV sensitive photo initiators (such as, e.g., UV curable acrylic inks). Even though the impact of UV irradiation (pixel shrinkage) on OLED devices is the same as described above, the requirements for the material selection are different. To improve UV stability of the dielectric material from UV irradiance (which refers to wavelengths of 300 nm to 400 nm), materials with bond dissociation energy greater than 400 kJ/mol are preferable. This would be the requirement for material selection and acrylates would be one of the materials that would satisfy this requirement. Namely, for C═O, the bond dissociation energy amounts to 749 kJ/mol (7.8 eV). For C—O, the bond dissociation energy amounts to 1076 kJ/mol (11.1 eV). For OC═O, the bond dissociation energy amounts to 532 kJ/mol (5.5 eV). For CH3CO—OCH3, the bond dissociation energy amounts to 406 kJ/mol (4.2 eV).

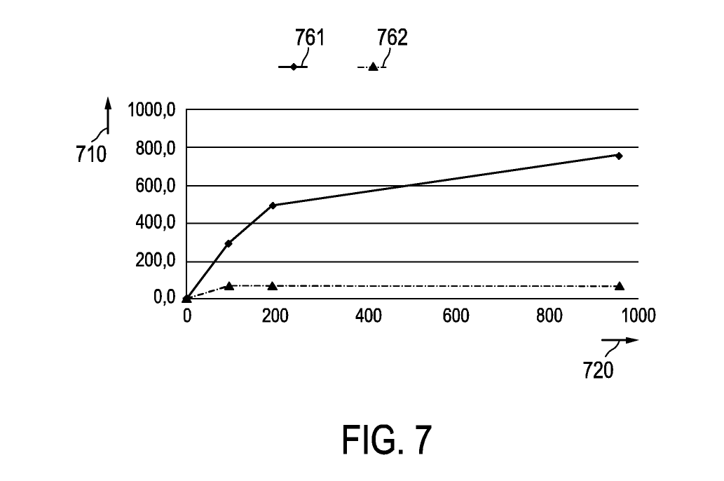

FIG. 7 shows schematically and exemplarily experimental data on pixel shrinkage as a function of time upon UV exposure. More specifically, FIG. 7 shows pixel shrinkage 710 (in μm) in Novolac (data labeled 761) and in acrylic based ink (data labeled 762) as a function of time 720 (in hours) exposed to UV irradiation with spectral distribution according to the CIE publication 85, table 4. As can be seen from FIG. 7, OLED devices with acrylic based dielectric ink show reduced pixel shrinkage compared to standard resist used in photo-lithographic processes.

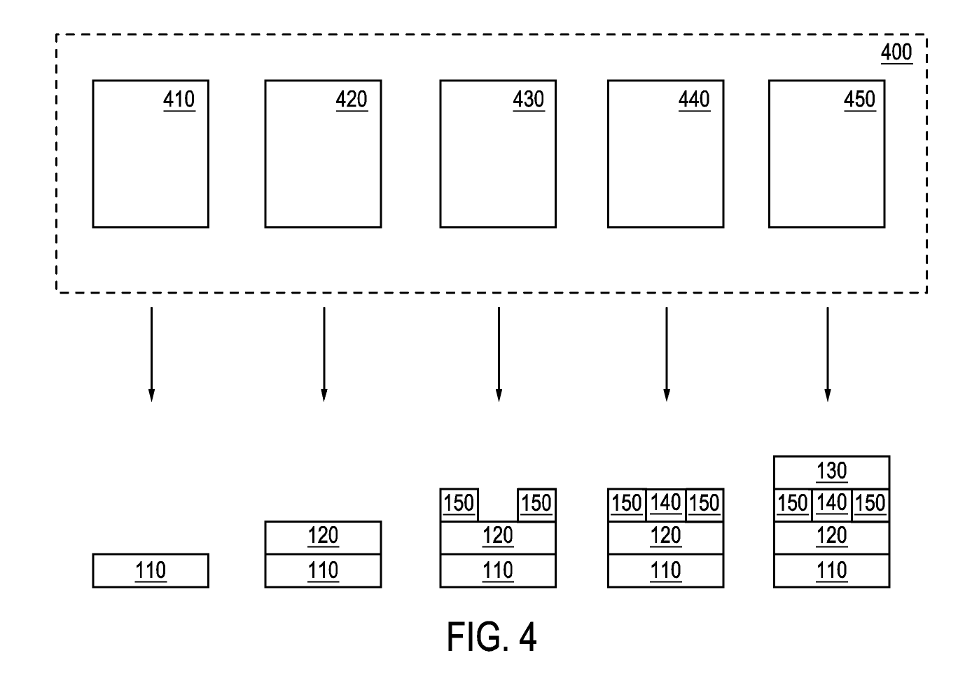

FIG. 4 shows schematically and exemplarily an embodiment of a fabrication apparatus 400 for fabricating an organic light emitting diode 100. The fabrication apparatus 400 comprises: a substrate providing unit 410 for providing a substrate layer 110; an electrode arranging unit 420 for arranging a first electrode layer 120 on the substrate layer 110; an electrode providing unit 430 for providing a second electrode layer 130; an active layer arranging unit 440 for arranging an active layer 140 in-between the first and second electrode layers 120, 130; and a dielectric layer providing unit 450 for providing a dielectric layer 150 to provide an electrical isolation between the first and second electrodes 120, 130. The dielectric layer 150 comprises a dielectric material configured to not produce any by-products during a curing process. A typical manufacturing sequence involves depositing the layers in the following order: substrate 110, first electrode (e.g., anode) 120 and pattern, dielectric layer 150 and pattern, active layer(s) 140, second electrode (e.g., cathode) 130, and encapsulation (not shown).

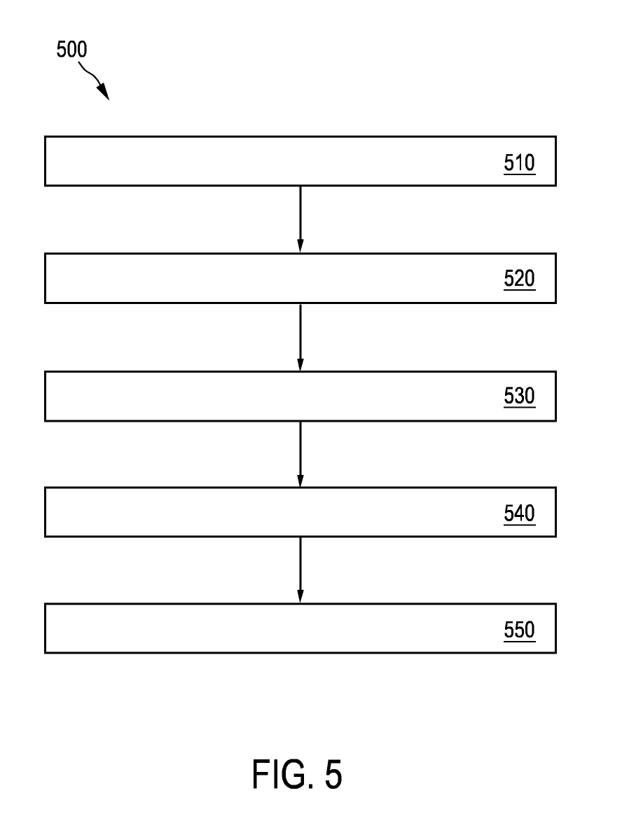

FIG. 5 shows schematically and exemplarily an embodiment of a fabrication method 500 for fabricating an organic light emitting diode 100. The fabrication method 500 comprises the steps of providing 510 a substrate layer 110; arranging 520 a first electrode layer 120 on the substrate layer 110; providing 530 a dielectric layer 150, where the dielectric layer 150 comprises a dielectric material configured to produce a reduced amount of or no by-products during a curing process; providing 540 an active layer 140; and providing 550 a second electrode layer 130.

An example application of the invention is in transparent electrical insulation layers to realize signs, symbols or customized patterns in OLEDs. However, the invention can of course also be used with simple OLEDs without signs, symbols and the like.

The invention can be used in transparent electrical insulation of fine grids or laterally patterned large area OLEDs.

The invention can further be used as a moisture barrier for OLEDs.

All arrangements of fabrication apparatus 400 can be controlled by fabrication method 500 in accordance with the invention, in particular, with the embodiment of fabrication method 500 described above with reference to FIG. 5.

Although in the above described embodiments fabrication apparatus 400 has been described as comprising substrate providing unit 410, electrode arranging unit 420, electrode providing unit 430, active layer arranging unit 440, and a dielectric layer providing unit 450, these embodiments are preferred embodiments only and in another embodiment the fabrication apparatus 400 can comprise these units in a distributed fashion, such as, e.g., in different locations.

Although in the above described embodiments certain configurations of organic light emitting device 100 are shown, the invention is not limited to a certain configuration of organic light emitting device 100. In an embodiment, the dielectric layer is not located between first electrode layer 120 and active layer 140, but between active layer 140 and second electrode layer 130.

Although in the above described embodiments certain configurations of fabrication apparatus 400 are shown, the invention is not limited to a certain configuration of fabrication apparatus 400. In an embodiment, active layer 140 is provided before providing second electrode layer 130. In another embodiment, dielectric layer 150 is provided before providing active layer 140.

Although in the above described embodiments certain configurations of fabrication method 500 are shown, the invention is not limited to a certain order of steps of fabrication method 500. In an embodiment, providing 550 a dielectric layer 150 is performed before arranging 540 an active layer 140 in-between the first and second electrode layers 120, 130. In another embodiment, providing 530 a second electrode layer 130 and arranging 540 an active layer 140 in-between the first and second electrode layers 120, 130 comprises providing an active layer 140 on the first electrode layer 120 or on the dielectric layer 150 before providing a second electrode layer 130 on the active layer.

Other variations to the disclosed embodiments can be understood and effected by those skilled in the art in practicing the claimed invention, from a study of the drawings, the disclosure, and the appended claims.

In the claims, the word “comprising” does not exclude other elements or steps, and the indefinite article “a” or “an” does not exclude a plurality.

A single unit or device may fulfill the functions of several items recited in the claims. The mere fact that certain measures are recited in mutually different dependent claims does not indicate that a combination of these measures cannot be used to advantage.

The control of the fabrication apparatus in accordance with the above described fabrication method can be implemented as program code means of a computer program and/or as dedicated hardware.

A computer program may be stored/distributed on a suitable medium, such as an optical storage medium or a solid-state medium, supplied together with or as part of other hardware, but may also be distributed in other forms, such as via the Internet or other wired or wireless telecommunication systems.

Any reference signs in the claims should not be construed as limiting the scope.

The present invention relates to organic light emitting diodes (OLEDs) wherein organic photoresist layers are used as dielectric layers for electrical isolation. When organic photoresist layers are used as dielectric layers in OLEDs, a problem called “pixel shrinkage” may occur. According to the invention, the problem of pixel shrinkage can be solved by using an acrylic resin such as methyl methacrylate or a solution of polyimide in gamma-butyrolactone to form the dielectric layer. There is provided an organic light emitting diode comprising: a substrate layer; a first electrode layer; a second electrode layer; an active layer in-between the first and second electrode layers; and a dielectric layer configured to provide an electrical isolation between the first and second electrodes. The dielectric layer comprises a dielectric material configured to produce a reduced amount of or no by-products during a curing process.

1. An organic light emitting diode comprising:
a substrate layer;
a first electrode layer arranged on the substrate layer;
a second electrode layer;
an active layer for emitting visible light, wherein the active layer is arranged in-between the first and second electrode layers; and
a dielectric layer configured to provide an electrical isolation between the first and second electrodes, the dielectric layer being deposited as a pattern on the first electrode layer, covering at least one edge of at least one of the first and second electrodes, and at least one side of the dielectric layer being covered by the second electrode layer;
wherein the dielectric layer is in direct contact with the active layer and comprises a dielectric material chosen from the group consisting of an acrylic resin, an acrylic-based resin, a methyl methacrylate, an unsaturated polyester, a polyurethane acrylate, an epoxy acrylate, a polyimide, and an epoxy imide.

2. The organic light emitting diode according to claim 1, wherein the dielectric material is solvent-free, and/or wherein the dielectric material is hydrophobic.

3. The organic light emitting diode according to claim 1, wherein the dielectric material is at least partially transparent to visible light.

4. The organic light emitting diode according to claim 1, wherein the dielectric layer is deposited by a direct printing technique.

5. The organic light emitting diode according to claim 1, wherein the first electrode layer is an anode layer, and wherein the second electrode layer is a cathode layer.

6. The organic light emitting diode according to claim 5, wherein the anode layer comprises an Indium-Tin-Oxide layer, and/or wherein the cathode layer comprises an Aluminium layer.

7. The organic light emitting diode according to claim 1, wherein the first electrode layer is a patterned transparent electrode layer.

8. The organic light emitting diode according to claim 1, wherein the second electrode layer comprises a transparent electrode layer and/or a light-reflecting layer configured to pass visible light emitted from the active layer through the substrate layer.

9. The organic light emitting diode according to claim 1, wherein the dielectric material is selected from the group consisting of a material with higher bond dissociation energy, a material with UV sensitive photo initiators, and a UV curable acrylic ink.

10. A fabrication method for fabricating an organic light emitting diode according to claim 1, wherein the fabrication method comprises the steps of
providing a substrate layer;
arranging a first electrode layer on the substrate layer;
providing a dielectric layer;
providing an active layer; and
providing a second electrode layer;
wherein the active layer is arranged in-between the first and second electrode layers;
wherein the dielectric layer provides an electrical isolation between the first and second electrodes, the dielectric layer being deposited as a pattern on the first electrode layer, covering at least one edge of at least one of the first and second electrodes, and at least one side of the dielectric layer being covered by the second electrode layer; and
wherein the dielectric layer is in direct contact with the active layer and comprises a dielectric material chosen from the group consisting of an acrylic resin, an acrylic-based resin, a methyl methacrylate, an unsaturated polyester, a polyurethane acrylate, an epoxy acrylate, a polyimide, and an epoxy imide.
